(19) United States
(12) Patent Application Publication
(10) Pub. No.: US 2019/0066906 A1
(43) Pub. Date: Feb. 28, 2019

(54) POWER CONVERSION DEVICE

(71) Applicant: Mitsubishi Electric Corporation, Tokyo (JP)

(72) Inventors: Takashi HIRATSUKA, Tokyo (JP); Takashi KUMAGAI, Tokyo (JP); Yasunori OTSUKA, Tokyo (JP); Yuichiro OBAYASHI, Tokyo (JP)

(73) Assignee: Mitsubishi Electric Corporation, Tokyo (JP)

(21) Appl. No.: 16/080,473

(22) PCT Filed: Apr. 25, 2016
(86) PCT No.: PCT/JP2016/062900

§ 371 Date: Aug. 28, 2018

(51) Int. Cl. H01F 27/28; H01F 27/22; H01F 27/24; H01F 27/02; H05K 1/18; H01F 27/29; H02M 3/335

(52) U.S. Cl. CPC H01F 27/2804; H01F 27/22; H01F 27/24; H05K 2201/1003; H05K 1/18; H01F 27/29; H02M 3/33569; H01F 27/02

(57) ABSTRACT

A power conversion device includes: planar type coil components having plate-like winding members and cores attached to the winding members; a housing having recessed portions in which the coil components are accommodated in vertical arrangement; and fillers with which gaps between the recessed portions and the coil components are filled.

### TECHNICAL FIELD

The present invention relates to a power conversion device.

### BACKGROUND ART

In the related art, a transformer and a reactor are used in a power conversion device. In a transformer and a reactor, a component having an iron core (hereinafter referred to as “core”) including a permanent magnet such as a ferrite magnet and a winding obtained by winding an insulated electric wire such as an enameled wire around the core, a so-called “coil component” is used.

Since it is difficult to miniaturize coil components in the related art, there is a problem that a power conversion device is large. To solve this problem, a thin coil component having a substantially plate-like member (hereinafter referred to as “winding member”) that serves as a winding and a core attached to the winding member, a so-called “planar type” coil component has been developed (e.g. see Patent Literature 1).

### CITATION LIST

### Patent Literatures

Patent Literature 1: JP 2012-134424 A

### SUMMARY OF INVENTION

### Technical Problem

In a planar type coil component, since a winding member generates heat by electric conduction, heat radiation is required. In general, the thermal conductivity of a core is lower as compared to a winding member (for example, the thermal conductivity of a ferrite magnet used for the core is 4 to 5 watts per meter Kelvin [W/mK], which is a value about one hundredth of the thermal conductivity of a copper foil used for the winding member), and thus it is difficult to radiate heat from the winding member to the core. Therefore, it is preferable to allow the heat generated by the winding member to be released to a member having a thermal conductivity higher than that of the core, for example, a housing made of metal. In an induction apparatus of Patent Literature 1, heat radiation members (heat conduction members 150 and 151) are interposed between a winding member (secondary coil C11) and a housing (housing 110), thereby the heat generated by the winding member is released to the housing (see paragraphs [0048] to and FIG. 4 of Patent Literature 1).

Here, in a power conversion device in the related art using the planar type coil component, the coil component is arranged horizontally with respect to a housing. That is, the coil component is screwed to the housing in a state where only one of surfaces of the thin coil component is arranged to face the bottom surface of the housing. This structure can reduce the thickness of the power conversion device in the height direction, whereas the bottom area of the power conversion device is increased. Therefore, there is a problem that an installation area is increased. There is another problem in this structure that the heat radiation efficiency of the coil component is low because the facing area between the coil component and the housing is small.

To solve this problem, as a novel structure which is unknown in the related art, it is conceivable to arrange a planar type coil component vertically in a recessed portion in a housing. However, when a planar type coil component is simply arranged vertically in a recessed portion, it is difficult to screw the coil component to the housing. As a result, there is a problem that fixation of the coil component is unstable and thus the vibration resistance drops.

The present invention has been made to solve the problems as described above, and it is an object of the present invention to, in a power conversion device using a planar type coil component, improve the heat radiation efficiency of the coil component, to reduce an installation area, and to improve the vibration resistance.

### Solution to Problem

A power conversion device of the present invention includes: a planar type coil component having a plate-like winding member and a core attached to the winding member; a housing having a recessed portion in which the coil component is accommodated in vertical arrangement; and a filler with which a gap between the recessed portion and the coil component is filled.

### Advantageous Effects of Invention

Since a power conversion device of the present invention is configured as described above, heat radiation efficiency of a coil component can be improved, an installation area can be reduced, and the vibration resistance can be improved.

### BRIEF DESCRIPTION OF DRAWINGS

FIG. 1A is an exploded perspective view illustrating the main part of a first coil component according to a first embodiment of the present invention.

FIG. 1B is a perspective view illustrating the main part of the first coil component according to the first embodiment of the present invention.

FIG. 2A is an exploded perspective view illustrating the main part of a second coil component according to the first embodiment of the present invention.

FIG. 2B is a perspective view illustrating the main part of the second coil component according to the first embodiment of the present invention.

FIG. 3 is an exploded perspective view illustrating the main part of a power conversion device according to the first embodiment of the present invention.

FIG. 4A is an explanatory diagram of the first coil component according to the first embodiment of the present invention accommodated in a first recessed portion when viewed from above.

FIG. 4B is an explanatory diagram of the first coil component according to the first embodiment of the present invention accommodated in the first recessed portion when viewed from the front.

FIG. 4C is an explanatory diagram of the first coil component according to the first embodiment of the present invention accommodated in the first recessed portion when viewed from a side.

FIG. 5A is an explanatory diagram of the second coil component according to the first embodiment of the present invention accommodated in a second recessed portion when viewed from above.

FIG. 5B is an explanatory diagram of the second coil component according to the first embodiment of the present invention accommodated in the second recessed portion when viewed from the front.

FIG. 5C is an explanatory diagram of the second coil component according to the first embodiment of the present invention accommodated in the second recessed portion when viewed from a side.

FIG. 6 is a circuit diagram illustrating the main part of a power conversion circuit according to the first embodiment of the present invention.

FIG. 7 is a timing chart illustrating the operation of the power conversion circuit according to the first embodiment of the present invention.

FIG. 8 is an exploded perspective view illustrating the main part of a power conversion device according to a second embodiment of the present invention.

FIG. 9A is an explanatory diagram of a first coil component and a second coil component according to the second embodiment of the present invention accommodated in a third recessed portion when viewed from above.

FIG. 9B is an explanatory diagram of the first coil component and the second coil component according to the second embodiment of the present invention accommodated in the third recessed portion when viewed from the front.

FIG. 10 is an exploded perspective view illustrating the main part of a power conversion device according to a third embodiment of the present invention.

FIG. 11A is an explanatory diagram of a first coil component according to the third embodiment of the present invention accommodated in a first recessed portion when viewed from above.

FIG. 11B is an explanatory diagram of the first coil component according to the third embodiment of the present invention accommodated in the first recessed portion when viewed from the front.

FIG. 11C is an explanatory diagram of the first coil component according to the third embodiment of the present invention accommodated in the first recessed portion when viewed from a side.

### DESCRIPTION OF EMBODIMENTS

To describe the present invention further in detail, embodiments for carrying out the present invention will be described below with reference to the accompanying drawings.

### First Embodiment

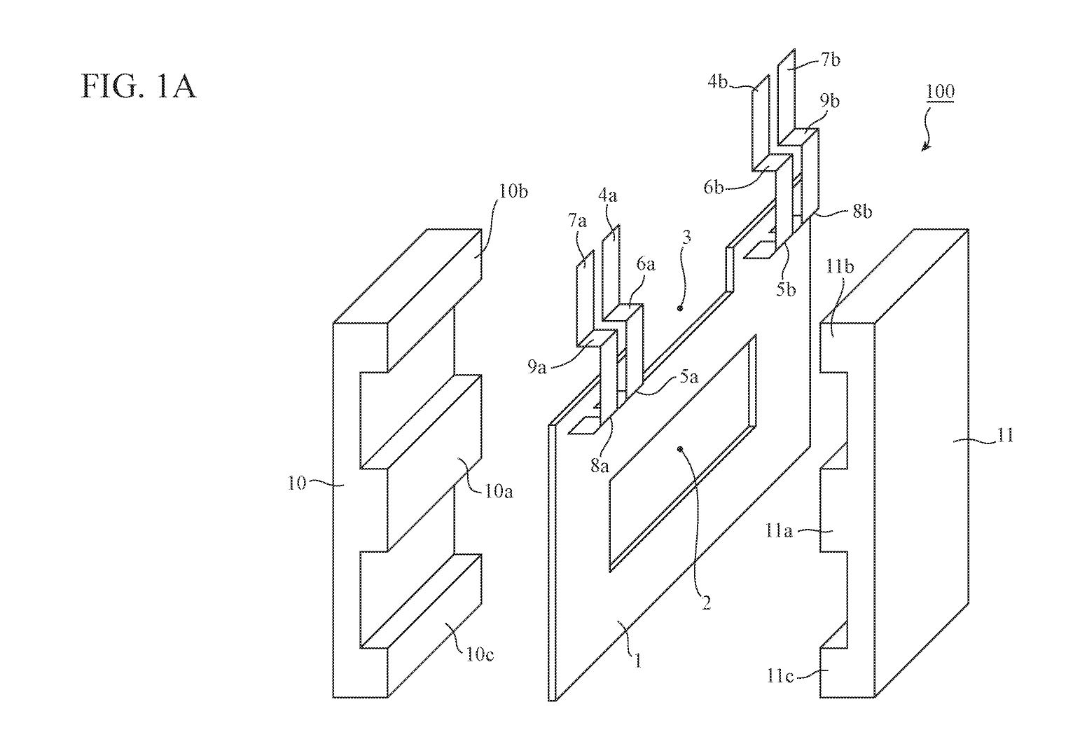

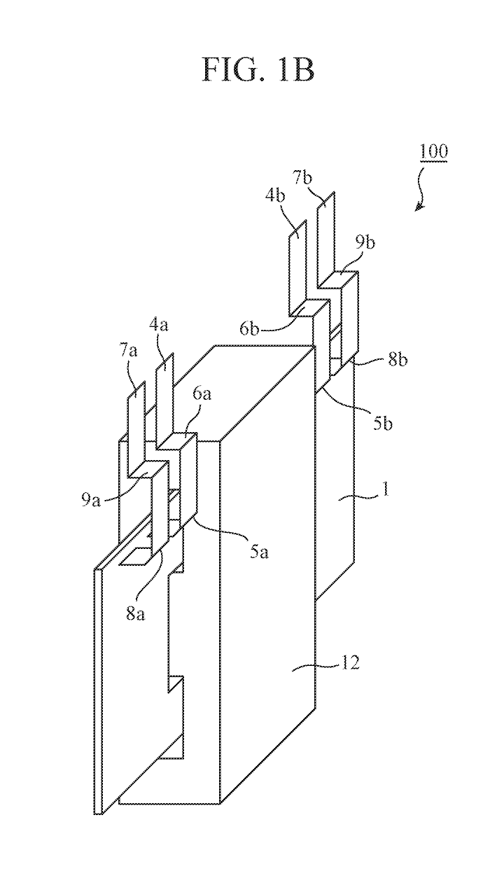

FIG. 1A is an exploded perspective view illustrating the main part of a first coil component according to a first embodiment of the present invention. FIG. 1B is a perspective view illustrating the main part of the first coil component according to the first embodiment of the present invention. With reference to FIG. 1, a first coil component 100 of the first embodiment will be described.

A winding member 1 includes a substantially rectangular printed circuit board and metal patterns of a winding shape (hereinafter referred to as “coil pattern”) provided for the printed circuit board. As a base material of the printed circuit board, for example, a glass epoxy resin is used. As the coil patterns, for example, copper foil is used. FIG. 1 is a diagram illustrating an example in which a multilayer substrate is used as the printed circuit board and the coil patterns are provided for inner layers of the multilayer substrate. That is, a first coil pattern is provided for a first conductor layer of the inner layers, and a second coil pattern is provided for a second conductor layer of the inner layers. The first coil pattern and the second coil pattern are electrically insulated from each other by an insulator layer between the first conductor layer and the second conductor layer. A through hole 2 is formed in a central portion of the printed circuit board, and a cutout portion 3 is formed on one of the long sides (hereinafter referred to as “upper side”) of the printed circuit board.

A pair of first terminals 4a and 4b is attached to the upper side of the printed circuit board. The first terminals 4a and 4b have: first bent portions 5a and 5b of a substantially L-shape at the base portions thereof, second bent portions 6a and 6b of a substantially Z-shape in the center portions thereof, and end portions extending upward from the printed circuit board. By providing at least one bent portion for each of the first terminals 4a and 4b, it is possible to relax mechanical stress generated between the printed circuit board of the winding member 1 and a main circuit printed board 38 which will be described later. The first terminals 4a and 4b are electrically connected with the first coil pattern.

A pair of second terminals 7a and 7b is attached to the upper side of the printed circuit board. The second terminals 7a and 7b have shapes similar to those of the first terminals 4a and 4b and have substantially L-shaped first bent portions 8a and 8b and substantially Z-shaped second bent portions 9a and 9b. The second terminals 7a and 7b are electrically connected to the second coil pattern. Hereinafter, the first terminals 4a and 4b and the second terminals 7a and 7b may be collectively referred to simply as “terminals”.

In the through hole 2 of the printed circuit board, middle legs 10a and 11a of a pair of E-shaped cores 10 and 11 arranged to face each other are inserted. One pair of outer legs 10b and 11b of the E-shaped cores 10 and 11 is inserted through the cutout portion 3 while the other pair of outer legs 10c and 11c faces the other long side (hereinafter referred to as “lower side”) of the printed circuit board. Each of the E-shaped cores 10 and 11 include a permanent magnet such as a ferrite magnet. That is, both the E-shaped cores 10 and 11 are burned products. The E-shaped cores 10 and 11 are integrally fixed using an adhesive tape (not illustrated) or the like. A core 12 is formed by the E-shaped cores 10 and 11.

The winding member 1, the terminals 4a, 4b, 7a, and 7b, and the core 12 form the first coil component 100 of a planar type. That is, the first coil pattern serves as a primary winding, the second coil pattern serves as a secondary winding, and the first coil component 100 serves as a transformer.

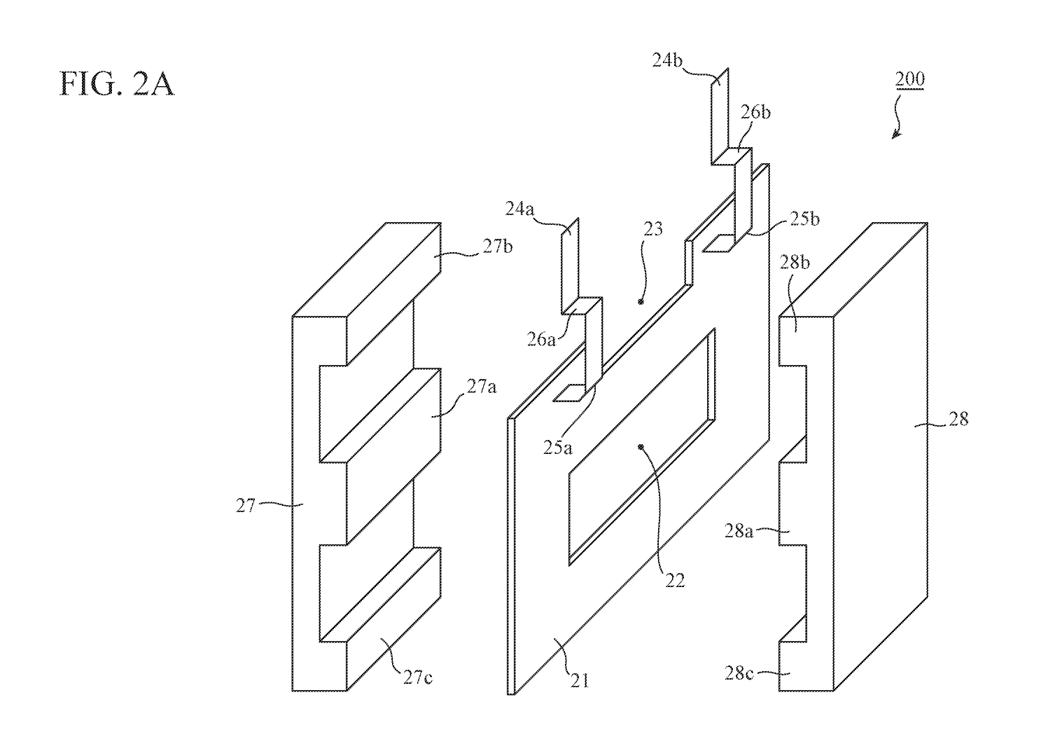

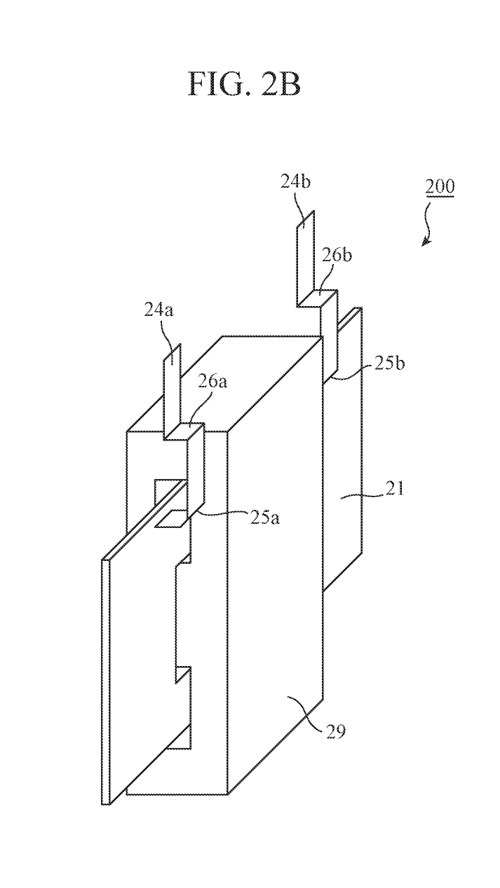

FIG. 2A is an exploded perspective view illustrating the main part of a second coil component according to the first embodiment of the present invention. FIG. 2B is a perspective view illustrating the main part of the second coil component according to the first embodiment of the present invention. With reference to FIG. 2, a second coil component 200 of the first embodiment will be described.

A winding member 21 includes a substantially rectangular printed circuit board and a coil pattern provided for the printed circuit board. As a base material of the printed circuit board, for example, a glass epoxy resin is used. As the coil pattern, for example, copper foil is used. FIG. 2 is a diagram illustrating an example in which a multilayer substrate is used as the printed circuit board and the coil pattern is provided for an inner layer of the multilayer substrate. A through hole 22 is formed in a central portion of the printed circuit board, and a cutout portion 23 is formed on an upper side of the printed circuit board.

A pair of terminals 24a and 24b is attached to the upper side of the printed circuit board. The terminals 24a and 24b have shapes similar to those of the terminals 4a, 4b, 7a, and 7b of the first coil component 100 and have substantially L-shaped first bent portions 25a and 25b and substantially Z-shaped second bent portions 26a and 26b. The terminals 24a and 24b are electrically connected with the coil pattern.

In the through hole 22 of the printed circuit board, middle legs 27a and 28a of a pair of E-shaped cores 27 and 28 arranged to face each other are inserted. One pair of outer legs 27b and 28b of the E-shaped cores 27 and 28 is inserted through the cutout portion 23 while the other pair of outer legs 27c and 28c faces a lower side of the printed circuit board. The E-shaped cores 27 and 28 are burned products similar to the E-shaped cores 10 and 11 of the first coil component 100. The E-shaped cores 27 and 28 are integrally fixed using an adhesive tape (not illustrated) or the like. A core 29 is formed by the E-shaped cores 27 and 28.

The winding member 21, the terminals 24a and 24b, and the core 29 form the second coil component 200 of a planar type. That is, the coil pattern serves as a winding, and the second coil component 200 serves as a reactor.

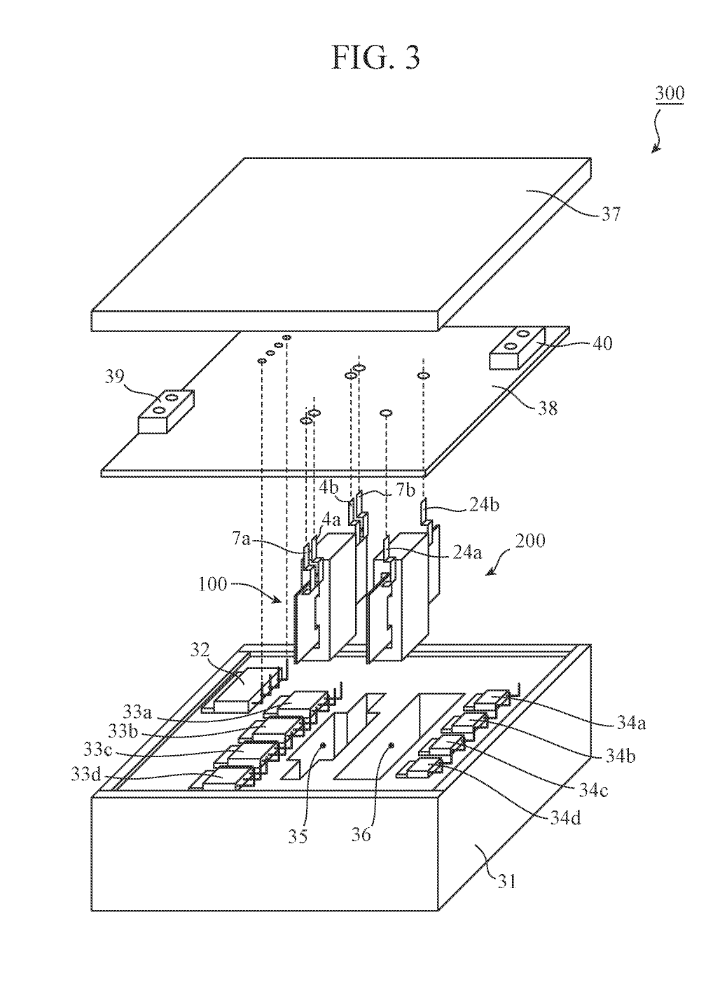

FIG. 3 is an exploded perspective view illustrating the main part of the power conversion device according to the first embodiment of the present invention. With reference to FIG. 3, a power conversion device 300 according to the first embodiment will be described.

A housing 31 has a substantially rectangular parallelepiped outer shape and is a cast product using a metal such as aluminum, that is, a so-called “die-cast molded product”. The housing 31 has a heat radiation mechanism (not illustrated). Specifically, for example, a heat sink (not illustrated) is provided on a surface of the housing 31. Alternatively, for example, a through hole (not illustrated) is formed in the housing 31 so that coolant flows inside the through hole. Alternatively, for example, the housing 31 has a connecting portion that is thermally connectable with a heat radiation device (not illustrated).

A first semiconductor element 32 is placed on an upper surface of the housing 31. The first semiconductor element 32 includes, for example, four diodes. Four second semiconductor elements 33a to 33d are further placed on the upper surface of the housing 31. Each of the second semiconductor elements 33a to 33d includes, for example, a metal-oxide-semiconductor field-effect transistor (MOSFET). Four third semiconductor elements 34a to 34d are further placed on the upper surface of the housing 31. Each of the third semiconductor elements 34a to 34d includes a diode, for example.

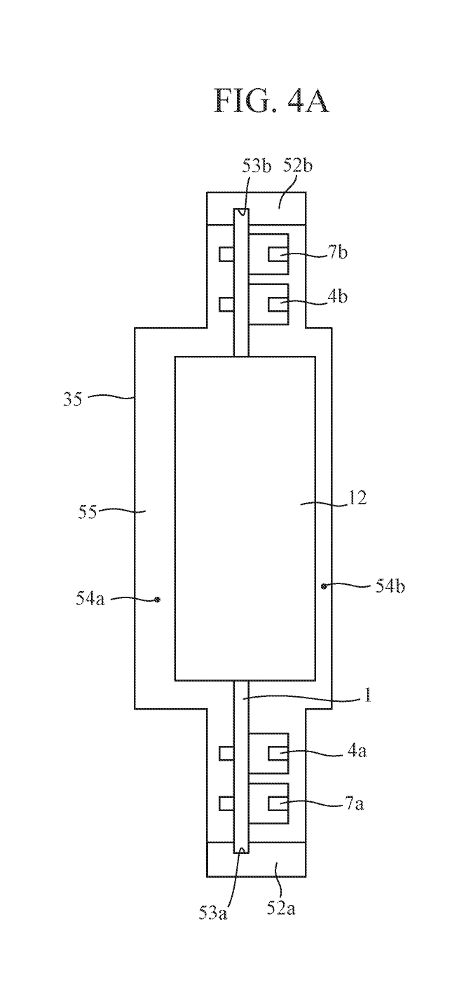

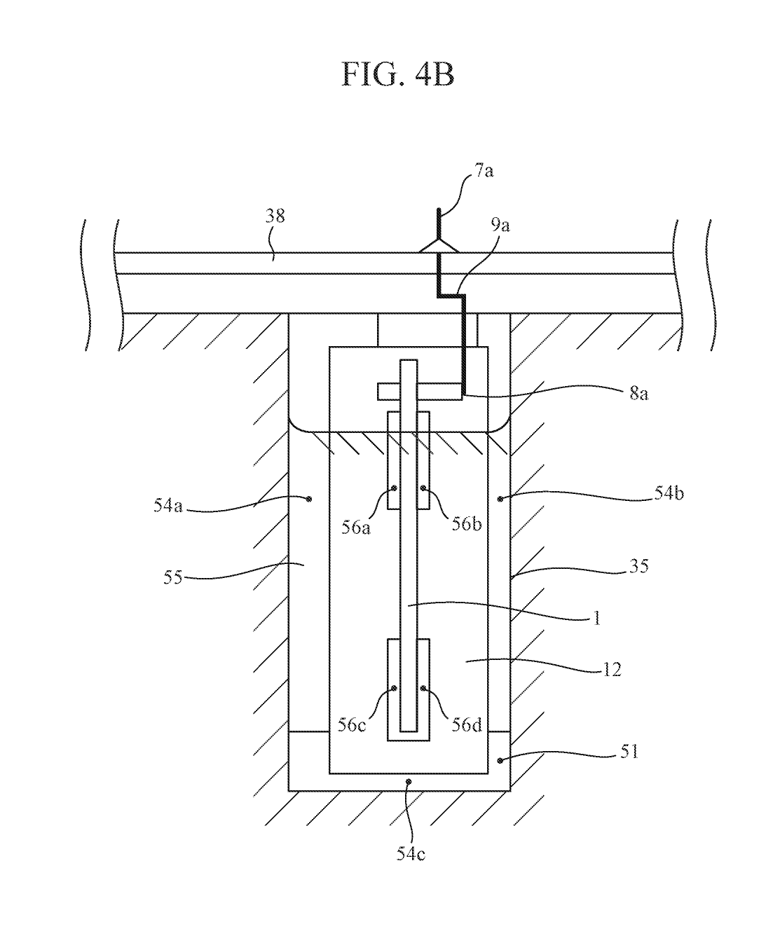

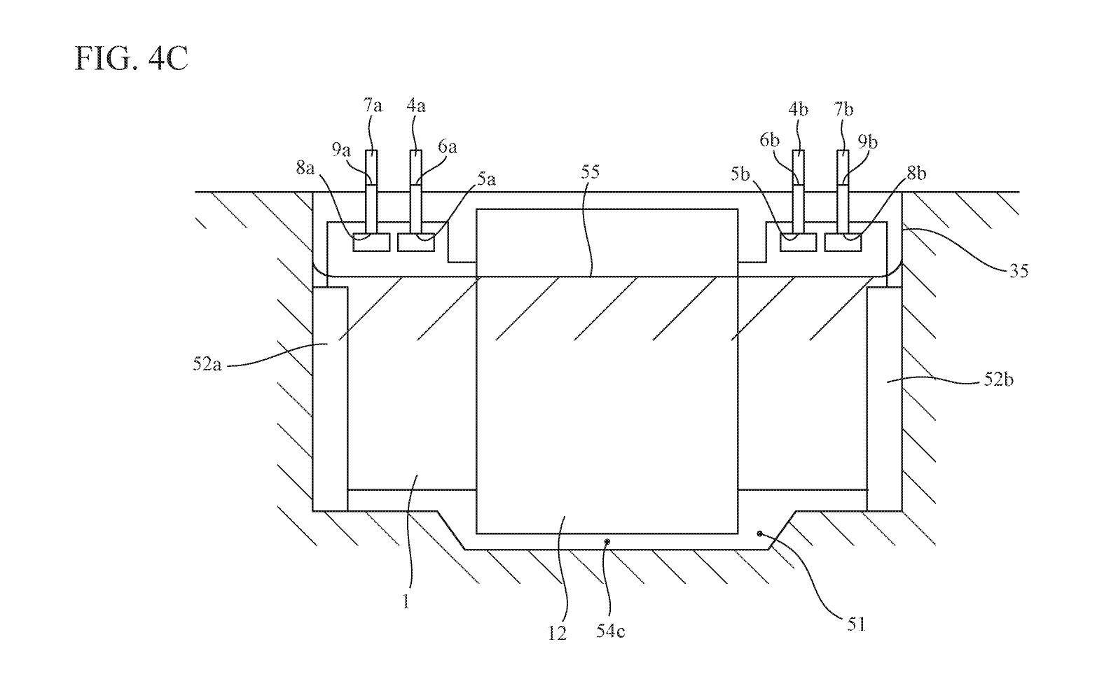

The housing 31 has a bottomed first recessed portion 35 that opens toward the upper surface. Inside the first recessed portion 35, the first coil component 100 is accommodated. The first coil component 100 is arranged vertically in the first recessed portion 35, and the terminals 4a, 4b, 7a, and 7b protrude from the opening of the first recessed portion 35. A detailed state inside the first recessed portion 35 will be described later with reference to FIG. 4.

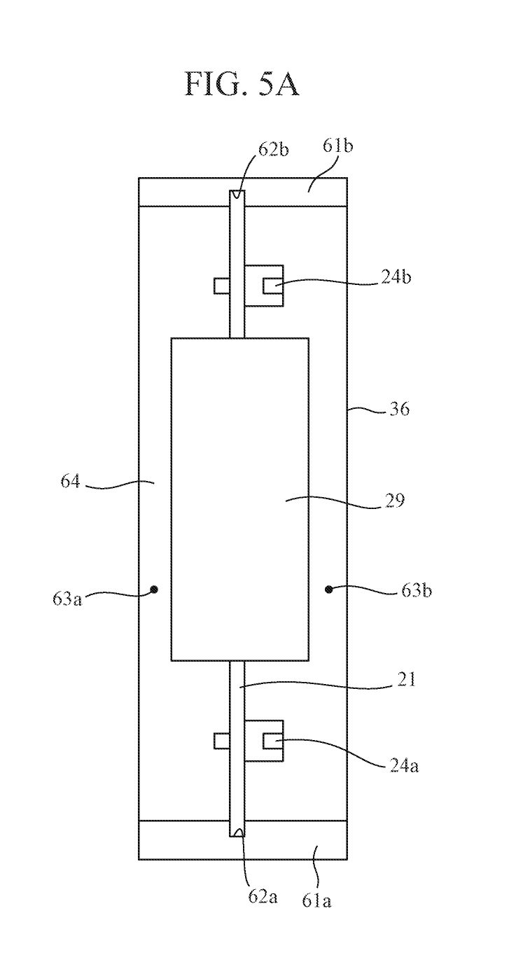

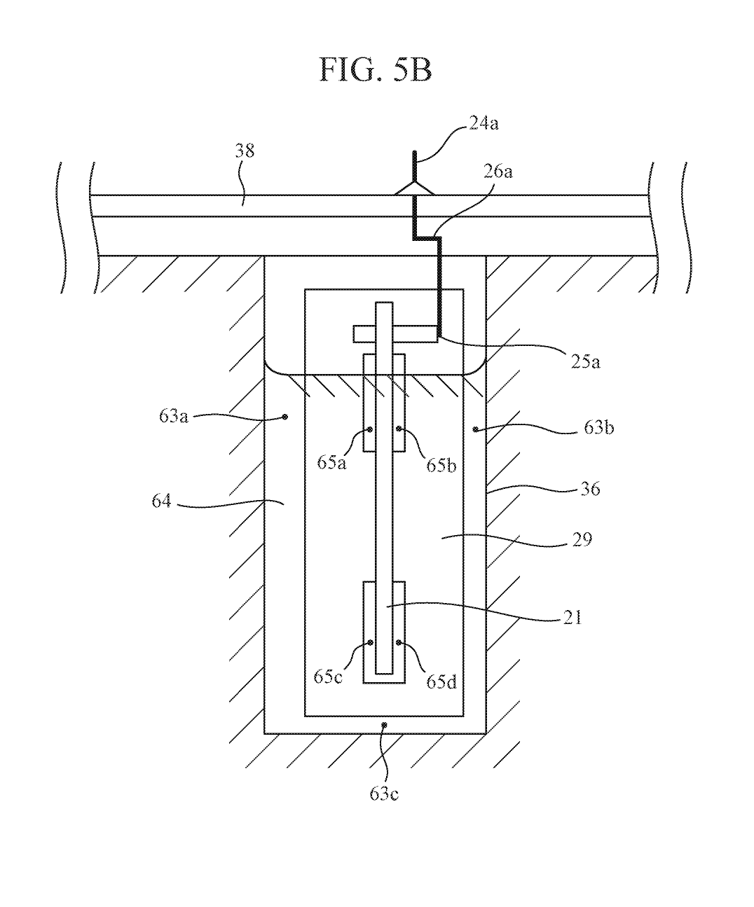

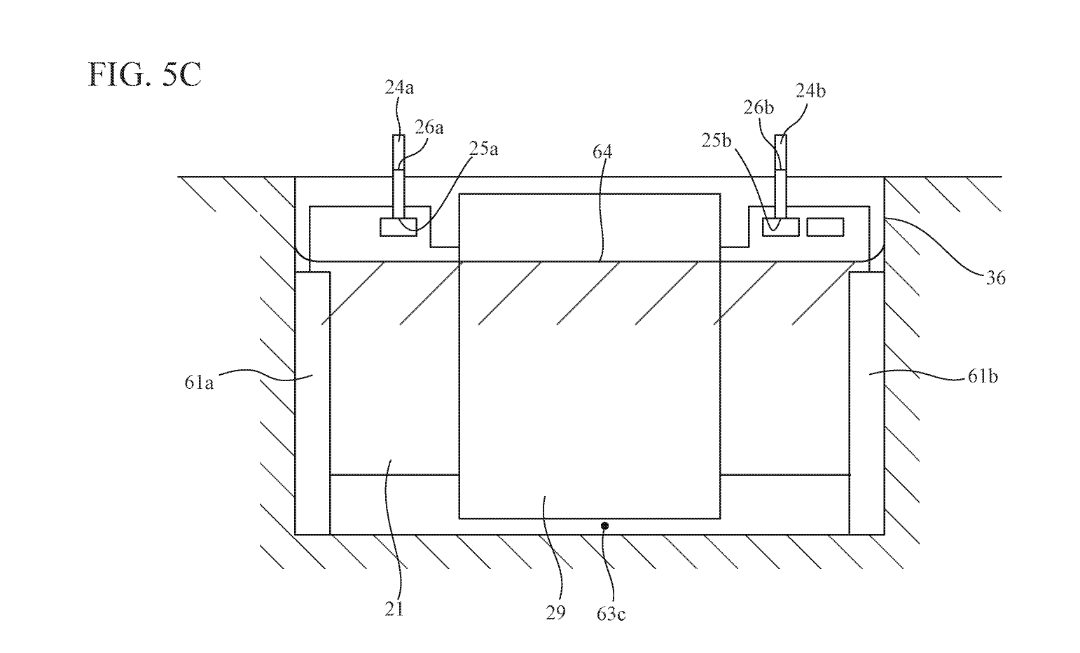

The housing 31 has a bottomed second recessed portion 36 that opens toward the upper surface. Inside the second recessed portion 36, the second coil component 200 is accommodated. The second coil component 200 is arranged vertically in the second recessed portion 36, and the terminals 24a and 24b protrude from the opening of the second recessed portion 36. A detailed state inside the second recessed portion 36 will be described later with reference to FIG. 5.

The upper surface of the housing 31 is covered with a lid 37 made of resin or metal. The lid 37 is fixed to the housing 31 by screws (not illustrated) or the like. The lid 37 may have a heat radiation mechanism similar to that of the housing 31.

The main circuit printed board 38 is arranged between the upper surface of the housing 31 and the lid 37. That is, the main circuit printed board 38 is arranged to face the openings of the first recessed portion 35 and the second recessed portion 36.

The main circuit printed board 38 has a plurality of through holes, so-called “through holes”. Terminals of the first semiconductor element 32, terminals of the second semiconductor elements 33a to 33d, terminals of the third semiconductor elements 34a to 34d, the terminals 4a, 4b, 7a, and 7b of the first coil component 100, and the terminals 24a and 24b of the second coil component 200 are individually soldered while passed through the corresponding through holes of the main circuit printed board 38. In FIG. 3, through holes for the second semiconductor elements 33a to 33d and through holes for the third semiconductor elements 34a to 34d are not illustrated.

An input terminal 39 and an output terminal 40 are mounted on the main circuit printed board 38. A first capacitor 41, a second capacitor 42, a voltage current detecting circuit 43, a photocoupler 44, and a control circuit 45 are further mounted on the main circuit printed board 38. In FIG. 3, the first capacitor 41, the second capacitor 42, the voltage current detecting circuit 43, the photocoupler 44, and the control circuit 45 are not illustrated.

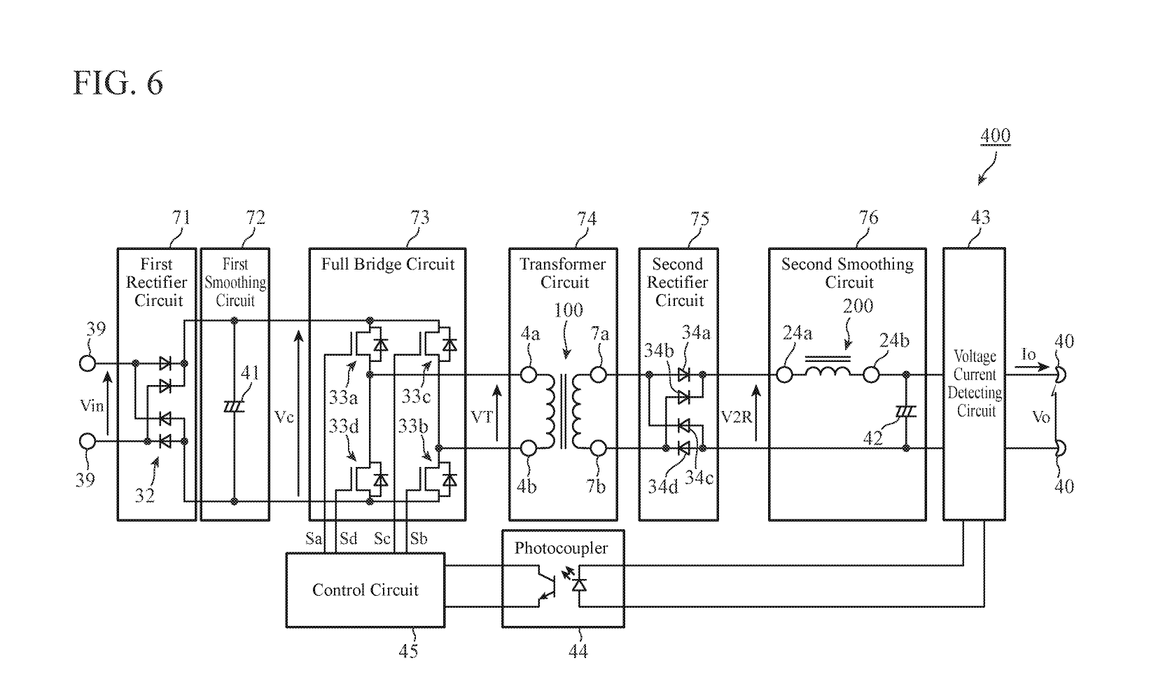

The input terminal 39, the first semiconductor element 32, the first capacitor 41, the second semiconductor elements 33a to 33d, the first coil component 100, the third semiconductor elements 34a to 34d, the second coil component 200, the second capacitor 42, the voltage current detecting circuit 43, the photocoupler 44, and the control circuit 45 are electrically connected by a metal pattern made of copper foil or other materials provided for the main circuit printed board 38. As a result, the main circuit for power conversion (hereinafter referred to as “power conversion circuit”) is configured. A circuit configuration of the power conversion circuit will be described later with reference to FIG. 6.

In this manner, the main part of the power conversion device 300 is configured. Note that the lid 37 is not an essential component among the components illustrated in FIG. 3. In the power conversion device 300, the lid 37 may be removed to reduce the weight and to reduce the number of parts.

Next, referring to FIG. 4, a state in the first recessed portion 35 will be described. As illustrated in FIG. 4, the first recessed portion 35 has a substantially cross-shaped opening, and has a deep bottom portion 51 at the center portion of the bottom surface. That is, the first recessed portion 35 has a shape conforming to the overall shape of the first coil component 100. This enables fixation of the first coil component 100 in the first recessed portion 35 to be stabilized and the thermal conduction resistance between the first recessed portion 35 and the first coil component 100 to be reduced. In addition, the first coil component 100 is arranged vertically inside the first recessed portion 35. That is, each of both surfaces of the planar type first coil component 100 faces a corresponding wall surface of the first recessed portion 35, and the terminals 4a, 4b, 7a, and 7b project upward from the opening of the first recessed portion 35.

A pair of substantially plate-like positioning members 52a and 52b is arranged in the first recessed portion 35 together with the first coil component 100. The positioning members 52a and 52b are in contact with corresponding wall surfaces of the first recessed portion 35, and both ends of the winding member 1 are individually fitted in grooves 53a and 53b formed in the positioning members 52a and 52b. The first coil component 100 is positioned with respect to the first recessed portion 35 by the positioning members 52a and 52b. In the positioned state, gaps 54a and 54b are provided between the first coil component 100 and corresponding wall surfaces of the first recessed portion 35, and a gap 54c is also provided between the first coil component 100 and the bottom surface of the first recessed portion 35.

Note that, since both the winding member 1 and the housing 31 are rigid, it is preferable to use a soft material such as a heat resistant resin for the positioning members 52a and 52b. That is, deformation of the positioning members 52a and 52b can absorb dimensional errors of the winding member 1 and the housing 31 and thereby reduce a mechanical load applied to the winding member 1.

The first recessed portion 35 is filled with a filler 55. As for the filler 55, it is preferable to use a resin filler that has insulation, has moderate flexibility also after curing, and has excellent thermal conductivity. Specifically, for example, a silicone resin is preferable.

The gaps 54a to 54c between the first coil component 100 and the first recessed portion 35 are filled with the filler 55. As a result, the first coil component 100 is fixed to the first recessed portion 35. In addition, the first coil component 100 and the first recessed portion 35 are electrically insulated from each other while thermally connected. Furthermore, gaps 56a to 56d between the winding member 1 and the core 12 are also filled with the filler 55. As a result, the winding member 1 and the core 12 are electrically insulated from each other while thermally connected.

Note that, in general, a resin filler having the above features is expensive. Therefore, the inside of the first recessed portion 35 may be only partially filled with the filler 55. In the example of FIG. 4, a volume of up to about 70% to 80% of the first recessed portion 35 is filled with the filler 55. As a result, the amount of the filler 55 used can be reduced, and the manufacturing cost of the power conversion device 300 can be reduced. Furthermore, since the first recessed portion 35 has a shape conforming to the overall shape of the first coil component 100, the amount of the filler 55 used can be further reduced.

Next, referring to FIG. 5, a state in the second recessed portion 36 will be described. As illustrated in FIG. 5, the second recessed portion 36 is substantially rectangular parallelepiped. That is, the second recessed portion 36 has a simple shape and thus can be easily molded by die-cast molding.

In the second recessed portion 36, a pair of substantially plate-like positioning members 61a and 61b is accommodated together with the second coil component 200. The positioning members 61a and 61b are in contact with corresponding wall surfaces of the second recessed portion 36, and both ends of the winding member 21 are individually fitted in grooves 62a and 62b formed in the positioning members 61a and 61b. The second coil component 200 is positioned with respect to the second recessed portion 36 by the positioning members 61a and 61b. In the positioned state, gaps 63a and 63b are provided between the second coil component 200 and corresponding wall surfaces of the second recessed portion 36, and a gap 63c is also provided between the second coil component 200 and the bottom surface of the second recessed portion 36. As for the positioning members 61a and 61b, like the positioning members 52a and 52b in the first recessed portion 35, it is preferable to use a soft material such as a heat resistant resin.

The second recessed portion 36 is filled with a filler 64. That is, the gaps 63a to 63c between the second coil component 200 and the second recessed portion 36 as well as the gaps 65a to 65d between the winding member 21 and the core 29 are filled with the filler 64. As for the filler 64, it is preferable to use a resin filler similar to the filler 55 in the first recessed portion 35. Furthermore from the viewpoint of reducing the amount of the filler 64 used, the second recessed portion 36 may be only partially filled with the filler 64. In the example of FIG. 5, a volume of up to about 70% to 80% of the second recessed portion 36 is filled with the filler 64.

Next, a circuit configuration of the power conversion circuit 400 will be described with reference to FIG. 6. As illustrated in FIG. 6, a first rectifier circuit 71, a first smoothing circuit 72, a full bridge circuit 73, a transformer circuit 74, a second rectifier circuit 75, a second smoothing circuit 76, and a voltage current detecting circuit 43 are sequentially connected between the input terminal 39 and the output terminal 40.

The first rectifier circuit 71 includes the first semiconductor element 32. The first smoothing circuit 72 includes the first capacitor 41. The full bridge circuit 73 includes the second semiconductor elements 33a to 33d. The transformer circuit 74 includes the first coil component 100 which serves as a transformer. The second rectifier circuit 75 includes the third semiconductor elements 34a to 34d. The second smoothing circuit 76 includes an LC filter using the second coil component 200 serving as a reactor and the second capacitor 42.

The voltage current detecting circuit 43 detects a voltage value of an output voltage Vo and a current value of an output current Io by the power conversion circuit 400. The voltage current detecting circuit 43 outputs an electric signal (hereinafter referred to as “feedback signal”) corresponding to the detected value to the photocoupler 44. The voltage current detecting circuit 43 includes, for example, a dedicated integrated circuit (IC) or the like.

The photocoupler 44 outputs a feedback signal input from the voltage current detecting circuit 43 to the control circuit 45 in a state where the voltage current detecting circuit 43 and the control circuit 45 are electrically insulated from each other. The photocoupler 44 includes, for example, a light emitting element electrically connected to the voltage current detecting circuit 43 and a light receiving element electrically connected to the control circuit 45.

The control circuit 45 includes a processor such as a microcontroller or a digital signal processor (DSP), for example. The control circuit 45 turns the second semiconductor elements 33a to 33d into an ON state by outputting signals Sa to Sd of a predetermined voltage (hereinafter referred to as “ON signal”) to the gate terminals of the second semiconductor elements 33a to 33d. In addition, the control circuit 45 turns the second semiconductor elements 33a to 33d into an OFF state by stopping the output of the ON signals Sa to Sd.

The control circuit 45 executes so-called “pulse width modulation (PWM) control” by turning on and off the second semiconductor elements 33a to 33d. Here, the control circuit 45 sets the pulse widths of the ON signals Sa to Sd by using the feedback signal input from the photocoupler 44 so that values of the output voltage Vo and the output current Io are appropriate.

The input terminal 39, the first rectifier circuit 71, the first smoothing circuit 72, the full bridge circuit 73, the transformer circuit 74, the second rectifier circuit 75, the second smoothing circuit 76, the voltage current detecting circuit 43, the output terminal 40, the photocoupler 44, and the control circuit 45 form the power conversion circuit 400. That is, the power conversion circuit 400 illustrated in FIG. 6 includes a so-called “insulated-type full bridge AC/DC converter”.

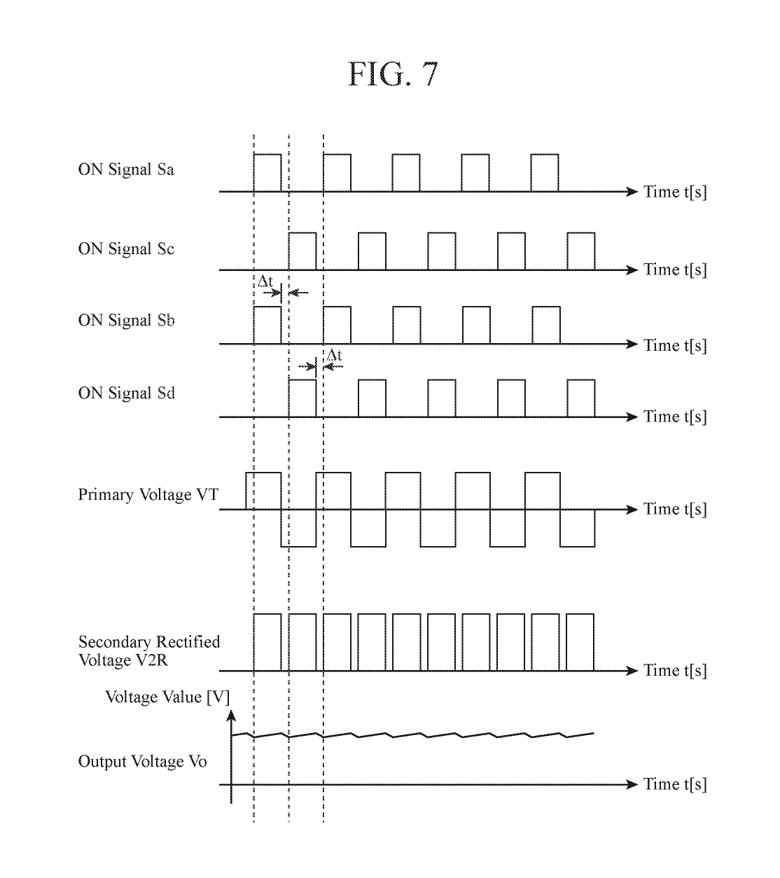

Next, with reference to FIGS. 6 and 7, the operation of the power conversion circuit 400 will be described mainly with an example in which the power conversion device 300 is applied to a so-called “on board charger (OBC)”. That is, the power conversion device 300 is mounted on an electric vehicle such as an electric vehicle (EV), a hybrid electric vehicle (HEV), or a plug-in hybrid electric vehicle (PHEV). The output terminal 40 is electrically connected to a driving battery mounted on the electric vehicle. The input terminal 39 is electrically connected to an AC power supply provided outside the electric vehicle.

An AC voltage is input to the input terminal 39. This input voltage Vin is rectified by the first rectifier circuit 71 and then smoothed by the first smoothing circuit 72. The voltage after smoothing by the first smoothing circuit 72 (hereinafter referred to as “primary smoothed voltage”) Vc is input to the full bridge circuit 73.

The control circuit 45 alternately outputs ON signals Sa and Sb for the two second semiconductor elements 33a and 33b and ON signals Sc and Sd for the other second semiconductor elements 33c and 33d as illustrated in FIG. 7. As a result, the second semiconductor elements 33a and 33b and the second semiconductor elements 33c and 33d are alternately turned on. As a result, an output voltage of the full bridge circuit 73, that is, the primary voltage VT of the transformer circuit 74 is an AC voltage of a rectangular wave as illustrated in FIG. 7. Note that, the primary voltage VT of the transformer circuit 74 has a phase difference with respect to the ON signals Sa to Sd, due to a counter electromotive force caused by the excitation energy. Therefore, an OFF time Δt is provided between the ON signals Sa and Sb and the ON signals Sc and Sd.

The secondary voltage of the transformer circuit 74 is subjected to full-wave rectification by the second rectifier circuit 75. The rectified voltage V2R (hereinafter referred to as “secondary rectified voltage”) by the second rectifier circuit 75 is smoothed by the second smoothing circuit 76. The voltage after smoothing by the second smoothing circuit 76 is obtained as the output voltage Vo. By the output voltage Vo, the driving battery connected to the output terminal 40 is charged.

Next, the effect of the power conversion device 300 will be described with reference to FIGS. 1 to 5. Hereinafter, the first coil component 100 and the second coil component 200 may be collectively referred to simply as “coil components”. Also, the first recessed portion 35 and the second recessed portion 36 may be collectively referred to simply as “recessed portions”.

In the power conversion device 300, the planar type coil components 100 and 200 are vertically arranged in the recessed portions 35 and 36. As a result, a bottom area of the power conversion device 300 is reduced, and thus an installation area can be reduced as compared to power conversion devices in the related art in which planar type coil components are horizontally arranged with respect to a housing.

Furthermore, the coil components 100 and 200 arranged vertically are fixed in the recessed portions 35 and 36 by the fillers 55 and 64, respectively. With this structure, it is possible to stabilize the fixation of the coil components 100 and 200 in the recessed portions 35 and 36 and to thereby improve the vibration resistance.

In addition, both surfaces of the planar type coil components 100 and 200 face the corresponding wall surfaces of the recessed portions 35 and 36, respectively, and the coil components 100 and 200 and the recessed portions 35 and 36 are thermally connected by the fillers 55 and 64, respectively. As a result, the heat radiation efficiency from the coil components 100 and 200 to the housing 31 can be improved.

Note that, in general, the thermal conductivity of a glass epoxy resin used for the printed circuit boards of the winding members 1 and 21 is about 0.5 [W/mK], which is even lower than the thermal conductivity (about 4 to 5 [W/mK]) of the ferrite magnet used for the cores 12 and 29. However, since the thickness of the printed circuit boards is thin (about 1 to 2 mm), heat radiation is not hindered, and the heat radiation efficiency of the coil components 100 and 200 can be improved.

In addition, since the coil components 100 and 200 are accommodated in the bottomed recessed portions 35 and 36, respectively, the radiation noise emitted from the coil components 100 and 200 is shielded by the housing 31 made of metal. This enables leakage of the radiation noise to the outside of the power conversion device 300 to be suppressed, thereby obtaining the power conversion device 300 of low radiation noise.

Furthermore, the main circuit printed board 38 is arranged to face the openings of the recessed portions 35 and 36. Thus, the metal pattern provided for the main circuit printed board 38 also functions to shield the radiation noise. This enables the radiation noise leaking outside the power conversion device 300 to be further suppressed, thereby obtaining the power conversion device 300 of further lower radiation noise.

Moreover, the terminals 4a, 4b, 7a, 7b, 24a, and 24b of the coil components 100 and 200 protrude from the corresponding openings of the recessed portions 35 and 36, and the terminals 4a, 4b, 7a, 7b, 24a, and 24b are inserted through the corresponding through holes of the main circuit printed board 38 which is arranged to face the openings. As a result, dedicated wiring members for connecting the terminals 4a, 4b, 7a, 7b, 24a, and 24b and the main circuit printed board 38 can be dispensed with, thereby enabling the number of parts of the power conversion device 300 to be reduced. As a result, work of connecting wiring members and fixing the wiring members can be dispensed with when the power conversion device 300 is manufactured, thereby enabling the manufacturing cost of the power conversion device 300 to be reduced. In addition, since the wire length between the winding members 1 and 21 and the main circuit printed board 38 is shortened, the radiation noise leaking to the outside of the power conversion device 300 can be further reduced. Furthermore, since the electrical length between the winding members 1 and 21 and the main circuit printed board 38 is shortened, an electrical loss with respect to the high frequency current flowing in the power conversion circuit 400 can be reduced.

In addition, in a planar type coil component in the related art, the width of a gap between a printed circuit board and a core is wide in order to electrically insulate a coil pattern and the core from each other, and thus there is a problem that it is difficult to sufficiently reduce the thickness of the coil component. Alternatively, a dedicated insulating member is provided between the printed circuit board and the core, and thus there is a problem that the number of components increases. On the other hand, in the power conversion device 300 of the first embodiment, the gaps 56a to 56d between the winding member 1 and the core 12 are filled with the filler 55 in the recessed portion 35, and the gaps 65a to 65d between the winding member 21 and the core 29 are filled with the filler 64 in the recessed portion 36. That is, since the winding members 1 and 21 and the cores 12 and 29 are electrically insulated from each other by the fillers 55 and 64 respectively, the thickness of the coil components 100 and 200 can be further reduced by reducing the widths of the gaps 56a to 56d and 65a to 65d between the winding members 1 and 21 and the cores 12 and 29. Furthermore, dedicated insulating members provided in the gaps 56a to 56d and 65a to 65d can be dispensed with, and thus the number of parts of the power conversion device 300 can be reduced.

In addition, since a glass epoxy resin is used for a printed circuit board in a planar type coil component in the related art, there is a problem that the insulation performance of an insulator layer in the printed circuit board is deteriorated due to moisture absorption of the glass fiber. On the other hand, in the power conversion device 300 of the first embodiment, spaces around the winding members 1 and 21 are filled with the fillers 55 and 64 respectively in the recessed portions 35 and 36. As a result, it is possible to suppress moisture absorption by the printed circuit boards of the winding members 1 and 21, thereby suppressing deterioration of the insulation performance. In other words, the moisture resistance of the winding members 1 and 21 can be improved.

Note that the terminals 4a, 4b, 7a, 7b, 24a, and 24b of the coil components 100 and 200 are only required to each have at least one bent portion, and thus are not limited to have a combination of the substantially L-shaped first bent portions 5a, 5b, 8a, 8b, 25a, and 25b and the substantially Z-shaped second bent portions 6a, 6b, 9a, 9b, 26a, and 26b, respectively.

Further, a control method of the power conversion circuit 400 is not limited to the PWM control. For example, the power conversion circuit 400 may execute control of a so-called “phase control” system. Furthermore, the circuit configuration of the power conversion circuit 400 is not limited to the insulated-type full bridge AC/DC converter illustrated in FIG. 6. Any circuit configuration may be employed as long as power conversion between a power source connected to the input terminal 39 and a power supply target connected to the output terminal 40 is performed.

In addition, the first semiconductor element 32 is not limited to four diodes, the second semiconductor elements 33a to 33d are not limited to four MOSFETs, and the third semiconductor elements 34a to 34d are not limited to four diodes. The types and the number of these semiconductor elements may be any types and any number as long as the types and the number depend on the circuit configuration of the power conversion circuit 400.

Furthermore, the first coil component 100 may be configured similarly to the second coil component 200 illustrated in FIG. 2, that is, may serve as a reactor. In addition, the second coil component 200 may be configured similarly to the first coil component 100 illustrated in FIG. 1, that is, serve as a transformer. Moreover, the number of the coil components 100 and 200 in the power conversion device 300 is not limited to two. The number and the types of the coil components 100 and 200 in the power conversion device 300 may be any number and any types as long as the number and the types depend on the circuit configuration of the power conversion circuit 400.

In addition, the first recessed portion 35 may have a shape similar to that of the second recessed portion 36 illustrated in FIG. 5, that is, a simple substantially rectangular parallelepiped. Furthermore, the second recessed portion 36 may have a shape similar to that of the first recessed portion 35 illustrated in FIG. 4, that is, a shape conforming to the overall shape of the second coil component 200. The shape of the first recessed portion 35 illustrated in FIG. 4 can stabilize the fixation of the coil components 100 and 200, reduce the thermal conduction resistance between the coil components 100 and 200 and the housing 31, and reduce the amount of the fillers 55 and 64 used. On the other hand, the shape of the second recessed portion 36 illustrated in FIG. 5 is easily molded by die-cast molding, and thus the manufacturing cost of the housing 31 can be reduced. As for the shape of each of the recessed portions 35 and 36 in the housing 31, either shape may be employed in consideration of these advantages.

Moreover, in each of the winding members 1 and 21, a coil pattern may be formed on a surface layer of the printed circuit board with the coil pattern exposed. Even in this case, in the power conversion device 300, the cores 12 and 29 and the corresponding coil patterns can be electrically insulated from each other and the coil patterns and the housing 31 can be electrically insulated from each other, by the fillers 55 and 64. However, from the viewpoint of preventing physical contact between the cores 12 and 29 and the corresponding coil patterns and securing an insulation distance therebetween, it is more preferable to provide each of the coil patterns for an inner layer of the multilayer substrate.

Furthermore, the winding members 1 and 21 are only required to be substantially plate-like members that serve as coils for the cores 12 and 29 and are not limited to the structure in which the coil pattern is provided for the printed circuit board. That is, the meaning of the term “plate-like” described in the claims of the present application is not limited to an exact plate shape but also includes a substantially plate-like shape.

In addition, the coil components 100 and 200 are only required to be arranged vertically in the recessed portions 35 and 36 respectively, and it is not necessary that both surfaces of the coil components 100 and 200 and the corresponding wall surfaces of the recessed portions 35 and 36 are strictly in parallel with each other, respectively. That is, the coil components 100 and 200 may be arranged vertically while inclined with respect to the corresponding wall surfaces of the recessed portions 35 and 36.

Moreover, the material of the positioning members 52a, 52b, 61a, and 61b is not limited to a heat resistant resin and may be metal. However, from the viewpoint of absorbing dimensional errors of the winding members 1 and 21 and the housing 31 and from the viewpoint of electrically insulating both ends of the winding members 1 and 21 and the housing 31 from each other, it is more preferable to use a heat resistant resin.

Instead of providing the grooves 53a, 53b, 62a, and 62b, the positioning members 52a, 52b, 61a, and 61b may fix the winding members 1 and 21 thereto by, for example, screwing, snap-fitting, or other means.

Alternatively, the positioning members 52a, 52b, 61a, and 61b may include respective arms for screwing that extend from upper end portions of the positioning members 52a, 52b, 61a, and 61b and along the upper surface of the housing 31, and the arms may be screwed to the upper surface of the housing 31.

Furthermore, the power conversion device 300 may have a structure in which the number of parts is further reduced by removing the positioning members 52a, 52b, 61a, and 61b. In this case, at the time of filling the recessed portions 35 and 36 with the fillers 55 and 64b, the coil components 100 and 200 are provisionally fixed inside the recessed portions 35 and 36 using a dedicated jig. After curing of the fillers 55 and 64b, the coil components 100 and 200 are positioned with respect to the recessed portions 35 and 36 and fixed thereto by the fillers 55 and 64b.

Furthermore in FIGS. 4 and 5, an example in which substantially the entire coil components 100 and 200 excluding the terminals 4a, 4b, 7a, 7b, 24a, and 24b are accommodated in the recessed portions 35 and 36 has been described; however, only the coil components 100 and 200 may be partially accommodated in the recessed portions 35 and 36 with the remaining portions protruding from the openings of the recessed portions 35 and 36. Specifically, for example, only lower half portions of the winding members 1 and 21 and the cores 12 and 29 may be accommodated in the recessed portions 35 and 36 while the upper half portions thereof protruding from the openings of the recessed portions 35 and 36.

Alternatively, the terminals 4a, 4b, 7a, 7b, 24a, and 24b may not protrude from the openings of the recessed portions 35 and 36 (that is, accommodated in the recessed portions 35 and 36) with the terminals 4a, 4b, 7a, 7b, 24a, and 24b electrically connected to the main circuit printed board 38 by tall connectors provided for the main circuit printed board 38. As a result, like in the structure in which the terminals 4a, 4b, 7a, 7b, 24a, and 24b protrude from the openings of the recessed portions 35 and 36, wiring members can be dispensed with, the radiation noise leaking to the outside of the power conversion device 300 can be reduced, and an electrical loss with respect to the high frequency current flowing in the power conversion circuit 400 can be reduced.

As described above, the power conversion device 300 according to the first embodiment includes: the planar type coil components 100 and 200 having the plate-like winding members 1 and 21 and the cores 12 and 29 attached to the winding members 1 and 21; the housing 31 having the recessed portions 35 and 36 in which the coil components 100 and 200 are accommodated in vertical arrangement; and the fillers 55 and 64 with which gaps between the recessed portions 35 and 36 and the coil components 100 and 200 are filled. By using the planar type coil components 100 and 200, disconnection of the windings does not occur, and manufacturing variations are reduced, and thus the reliability of the power conversion device 300 can be improved. Furthermore, by arranging the planar type coil components 100 and 200 vertically in the recessed portions 35 and 36, the heat radiation efficiency of the coil components 100 and 200 can be improved, and the installation area of the power conversion device 300 can be reduced. Furthermore, by filling the gaps between the recessed portions 35 and 36 and the coil components 100 and 200 with the fillers 55 and 64, the fixation of the coil components 100 and 200 in the recessed portions 35 and 36 can be stabilized, and thus the vibration resistance can be improved. Due to the improvement of the heat radiation efficiency, the reduction of the installation area, and the improvement of the vibration resistance, required specifications especially for the power conversion device 300 for onboard use can be satisfied, and it is possible to obtain the power conversion device 300 suitable for onboard use such as an OBC. Moreover, the fillers 55 and 64 can improve the insulation performance and the moisture resistance of the winding members 1 and 21.

In addition, the cores 12 and 29 are burned products, and the gaps between the cores 12 and 29 and the winding members 1 and 21 are filled with the fillers 55 and 64. As a result, the widths of the gaps 56a to 56d and 65a to 65d between the cores 12 and 29 and the winding members 1 and 21 can be reduced, and a dedicated insulation member can be dispensed with while electrical insulation between the cores 12 and 29 and the winding members 1 and 21 can be further ensured.

In addition, the winding members 1 and 21 include the multilayer substrates and the coil patterns provided for the inner layers of the multilayer substrates. This ensures the insulation distance between the coil patterns and the cores 12 and 29, thereby further ensuring the electrical insulation between the coil patterns and the cores 12 and 29.

In addition, the power conversion device 300 includes the main circuit printed board 38 arranged to face the openings of the recessed portions 35 and 36, and the terminals 4a, 4b, 7a, 7b, 24a, and 24b of the coil components 100 and 200 are electrically connected to the main circuit printed board 38. As a result, wiring members for connecting between the terminals 4a, 4b, 7a, 7b, 24a, and 24b and the main circuit printed board 38 can be dispensed with, thereby enabling the number of parts and the manufacturing cost to be reduced. Furthermore, the metal pattern for the power conversion circuit 400 included on the main circuit printed board 38 can prevent the radiation noise emitted from the coil components 100 and 200 from leaking to the outside of the power conversion device 300. Furthermore, the electrical length between the winding members 1 and 21 and the main circuit printed board 38 can be shortened, and thereby an electrical loss with respect to the high frequency current flowing in the power conversion circuit 400 can be reduced.

In addition, the coil components 100 and 200 are positioned with respect to the recessed portions 35 and 36 by the positioning members 52a, 52b, 61a, and 61b provided in the recessed portions 35 and 36. This can prevents the terminals 4a, 4b, 7a, 7b, 24a, and 24b from being damaged when the terminals 4a, 4b, 7a, 7b, 24a, and 24b are passed through the corresponding through holes of the main circuit printed board 38. Furthermore, the coil components 100 and 200 can be provisionally fixed before filling with the fillers 55 and 64. Moreover, by using a heat resistant resin for the positioning members 52a, 52b, 61a, and 61b, the insulation performance between the winding members 1 and 21 and the housing 31 can be improved.

### Second Embodiment

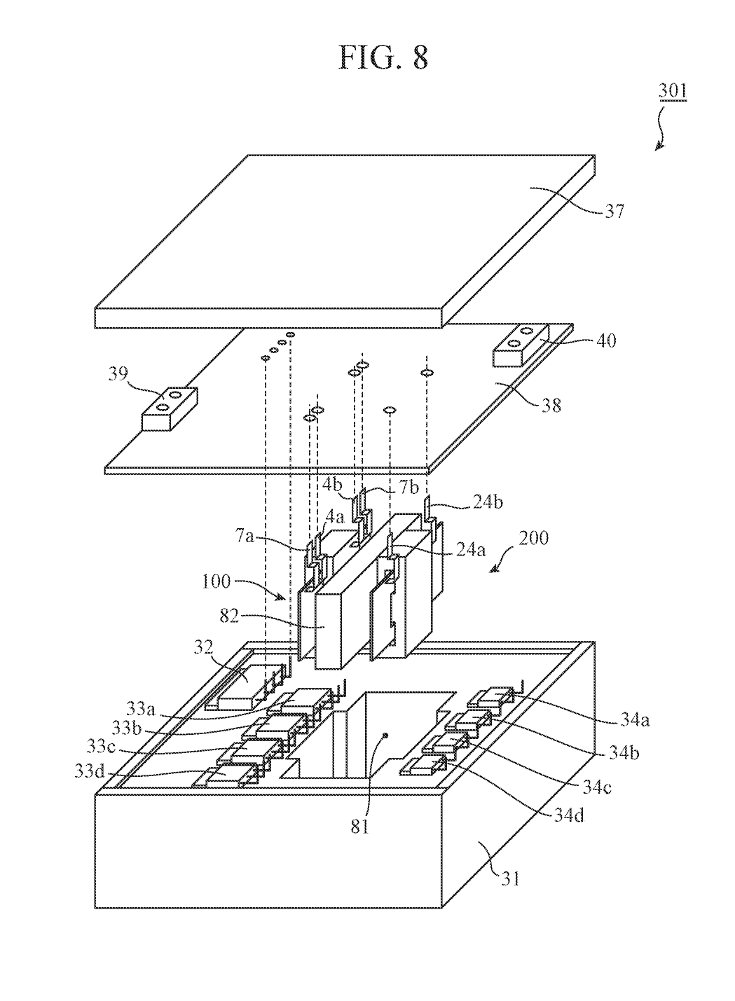

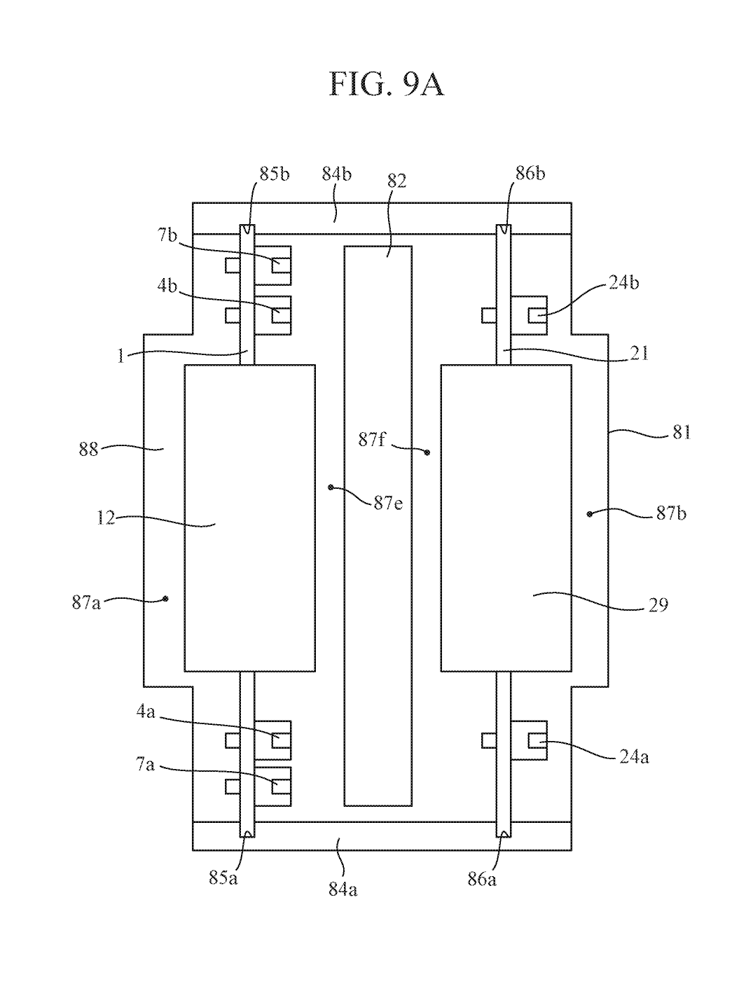

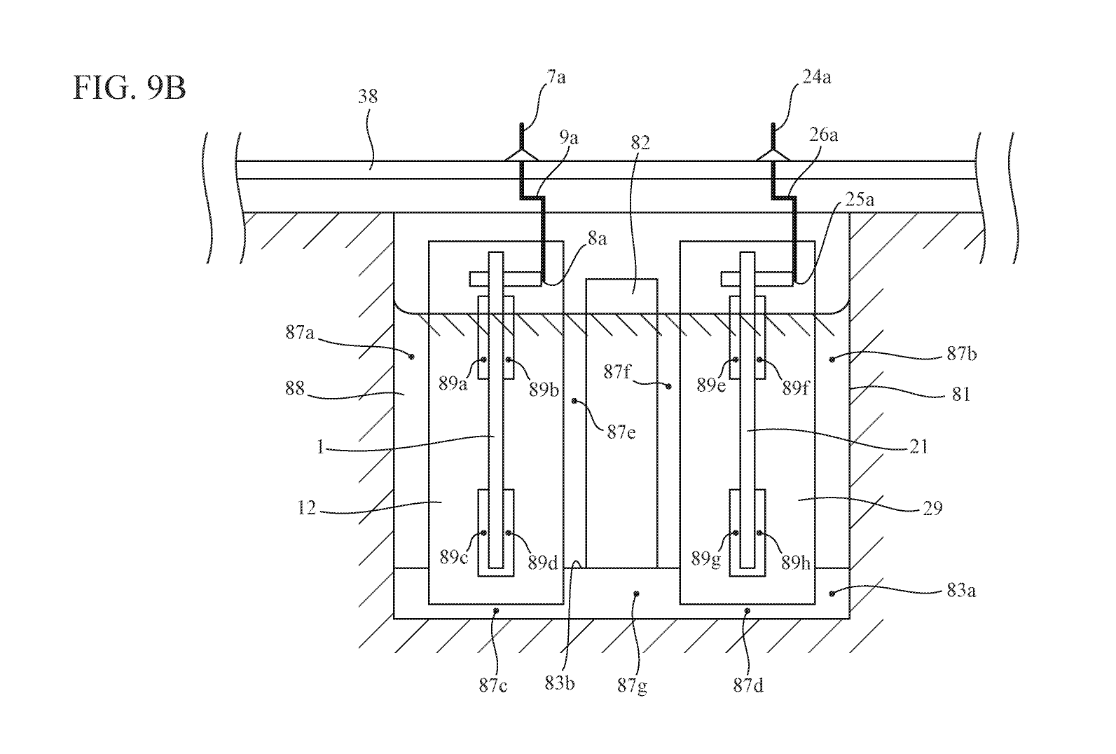

FIG. 8 is an exploded perspective view illustrating the main part of a power conversion device according to a second embodiment of the present invention. FIG. 9A is an explanatory diagram of a first coil component and a second coil component according to the second embodiment of the present invention accommodated in a third recessed portion when viewed from above. FIG. 9B is an explanatory diagram of the first coil component and the second coil component according to the second embodiment of the present invention accommodated in the third recessed portion when viewed from the front. With reference to FIGS. 8 and 9, a power conversion device 301 of the second embodiment will be described. Note that components similar to those of the power conversion device 300 illustrated in FIGS. 1 to 5 are denoted by the same symbols, and description thereof is omitted.

As illustrated in FIG. 8, a housing 31 has a bottomed third recessed portion 81 that opens toward the upper surface. A substantially plate-like partition wall member 82 is accommodated in the third recessed portion 81 together with a first coil component 100 and a second coil component 200. The partition wall member 82 is made of, for example, a metal similar to that of the housing 31 such as aluminum.

The substantially plate-like partition wall member 82, the planar type first coil component 100, and the planar type second coil component 200 are all vertically arranged in the third recessed portion 81 in a state where longitudinal directions thereof are aligned. That is, one of both surfaces of the first coil component 100 faces a corresponding wall surface of the third recessed portion 81 while the other surface faces a front surface of the partition wall member 82. One of both surfaces of the second coil component 200 faces a corresponding wall surface of the third recessed portion 81 while the other surface faces a back surface of the partition wall member 82. Terminals 4a, 4b, 7a, and 7b of the first coil component 100 and terminals 24a and 24b of the second coil component 200 protrude upward from an opening of the third recessed portion 81.

As illustrated in FIG. 9, the third recessed portion 81 has a substantially cross-shaped opening, and has a deep bottom portion 83a at the center portion of the bottom surface. That is, the shape of the third recessed portion 81 has a shape conforming to the overall shapes of the first coil component 100 and the second coil component 200 accommodated in the third recessed portion 81. This enables fixation of the first coil component 100 and the second coil component 200 in the third recessed portion 81 to be stabilized and the thermal conduction resistance between the first coil component 100 and the housing 31 as well as between the second coil component 200 and the housing 31 to be reduced.

In the third recessed portion 81, a pair of substantially plate-like positioning members 84a and 84b is accommodated together with the first coil component 100 and the second coil component 200. The positioning members 84a and 84b are in contact with corresponding wall surfaces of the third recessed portion 81, and both ends of a winding member 1 are individually fitted in first grooves 85a and 85b formed in the positioning members 84a and 84b while both ends of a winding member 21 are individually fitted in second grooves 86a and 86b. The first coil component 100 and the second coil component 200 are positioned with respect to the third recessed portion 81 by the positioning members 84a and 84b. In the positioned state, a gap 87a is provided between the first coil component 100 and a corresponding wall surface of the third recessed portion 81, and a gap 87b is also provided between the second coil component 200 and a corresponding wall surface of the third recessed portion 81. Furthermore, a gap 87c is provided between the first coil component 100 and the bottom surface of the third recessed portion 81, and a gap 87d is provided between the second coil component 200 and the bottom surface of the third recessed portion 81.

In addition, a gap 87e is provided between the partition wall member 82 and the first coil component 100, and a gap 87f is also provided between the partition wall member 82 and the second coil component 200. The partition wall member 82 is in contact with a portion 83b of the bottom surface of the third recessed portion 81 (hereinafter referred to as “shallow bottom portion”) which is different from the deep bottom portion 83a. As a result, the partition wall member 82 and the housing 31 are electrically connected and thermally connected. Between the partition wall member 82 and the deep bottom portion 83a, a gap 87g is provided.

The third recessed portion 81 is filled with a filler 88. For the filler 88, for example, it is preferable to use a resin filler similar to the fillers 55 and 64 of the first embodiment. The gaps 87a and 87c between the first coil component 100 and the third recessed portion 81 as well as gaps 89a to 89d between the winding member 1 and the core 12 are filled with the filler 88. The gaps 87b and 87d between the second coil component 200 and the third recessed portion 81 as well as gaps 89e to 89h between the winding member 21 and the core 29 are filled with the filler 88.

Moreover, the gap 87c between the partition wall member 82 and the first coil component 100, the gap 87d between the partition wall member 82 and the second coil component 200, and the gap 87g between the partition wall member 82 and the deep bottom portion 83a are also filled with the filler 88. As a result, the partition wall member 82 is fixed in the third recessed portion 81. In addition, the partition wall member 82 and the first coil component 100 are electrically insulated from each other while thermally connected. The partition wall member 82 and the second coil component 200 are electrically insulated from each other while thermally connected.

Note that the inside of the third recessed portion 81 may be only partially filled with the filler 88. In the example of FIG. 9, a volume of up to about 70% to 80% of the third recessed portion 81 is filled with the filler 88. As a result, the amount of the filler 88 used can be reduced, and the manufacturing cost of the power conversion device 301 can be reduced. In addition, since the third recessed portion 81 has a shape conforming to the overall shapes of the first coil component 100 and the second coil component 200, the amount of the filler 88 used can be further reduced.

In this manner, the main part of the power conversion device 301 is configured. Note that a circuit configuration and the operation of the power conversion circuit in the power conversion device 301 are similar to those described in the first embodiment with reference to FIGS. 6 and 7, and thus illustration and descriptions thereof are omitted.

Next, a method of manufacturing the power conversion device 301 will be described with a focus on the step of arranging the partition wall member 82, the positioning members 84a and 84b, the first coil component 100, and the second coil component 200 in the third recessed portion 81 and the step of filling the third recessed portion 81 with the filler 88.

First, the positioning members 84a and 84b, the first coil component 100 and the second coil component 200 are arranged inside the third recessed portion 81. As a result, the first coil component 100 and the second coil component 200 are positioned with respect to the third recessed portion 81 and temporarily fixed before filling with the filler 88.

Next, the third recessed portion 81 is filled with the filler 88. The filling amount at this time is an amount obtained by subtracting a volume corresponding to the volume of the partition wall member 82 from the final filling amount (a volume of about 70 to 80% of the third recessed portion 81) exemplified in FIG. 9.

Next, the partition wall member 82 is inserted between the first coil component 100 and the second coil component 200. At this time, the partition wall member 82 is buried in the filler 88, whereby the partition wall member 82 is positioned within the third recessed portion 81. In addition, by burying the partition wall member 82, the apparent volume of the filler 88 is increased, thus resulting in the state illustrated in FIG. 9. In this state, the filler 88 is cured.

Next, with reference to FIGS. 8 and 9, effects of the power conversion device 301 will be described. In the power conversion device 301, two coil components 100 and 200 are accommodated in one third recessed portion 81. As a result, a value of the aspect ratio of the opening shape (hereinafter simply referred to as “aspect ratio”) can be reduced in the third recessed portion 81 as compared to the first recessed portion 35 and the second recessed portion 36 of the first embodiment. In general, it is difficult to form a recessed portion having a high aspect ratio by die-cast molding, which leads to an increase in the manufacturing cost. By reducing the value of the aspect ratio of the third recessed portion 81, molding of the housing 31 is easy, and thus the manufacturing cost can be reduced.

In addition, in the power conversion device 301, each of both surfaces of the first coil component 100 faces corresponding one of a wall surface of the third recessed portion 81 or the partition wall member 82, and each of both surfaces of the second coil component 200 faces corresponding one of a wall surface of the third recessed portion 81 or the partition wall member 82. As a result, heat radiation efficiency of the coil components 100 and 200 can be improved like in the power conversion device 300 of the first embodiment in which both surfaces of the coil components 100 and 200 face the corresponding wall surfaces of the recessed portions 35 and 36.

In addition, the partition wall member 82 made of metal shields the radiation noise emitted from the second coil component 200. This prevents the radiation noise from being propagated to the first coil component 100 and thus prevents conduction noise due to the radiation noise from being superimposed on the output of the transformer circuit 74. As a result, the power conversion device 301 with reduced conduction noise can be obtained.

Furthermore, in the case where the recessed portion has a high aspect ratio and the filler has a high viscosity, the work of filling the gaps between the recessed portion and the coil component with the filler is difficult in a state where the planar type coil component is vertically arranged in the recessed portion. On the other hand, in the power conversion device 301 of the second embodiment, filling with the filler 88 is performed in a state where the positioning members 84a and 84b and the coil components 100 and 200 are arranged in the third recessed portion 81 having a low aspect ratio, and then the partition wall member 82 is inserted. As a result, even in the case where the filler 88 has a high viscosity, the filling work is easy, and the manufacturing cost of the power conversion device 301 can be further reduced.

Note that the partition wall member 82 may not be in contact with the shallow bottom portion 83b with a gap provided between the partition wall member 82 and the shallow bottom portion 83b. It is preferable that the width of the gap is set to a small value so that the partition wall member 82 and the shallow bottom portion 83b are electrically connected, that is, to such a degree that conduction at a high frequency by capacitive coupling is obtained. As a result, the shielding effect of the partition wall member 82 can be improved like in the structure in which the partition wall member 82 is in contact with the shallow bottom portion 83b.

Furthermore, the shape of the third recessed portion 81 may be any shape as long as the partition wall member 82, the positioning members 84a and 84b, and the coil components 100 and 200 can be accommodated, and is not limited to the shape illustrated in FIG. 9. The third recessed portion 81 may be, for example, a simple substantially rectangular parallelepiped. This allows molding of the housing 31 to be further easier.

Moreover, the material of the partition wall member 82 is not limited to metal, and a heat resistant resin having thermal conductivity may be used. However, from the viewpoint of enhancing the shielding effect against the radiation noise, it is more preferable to use metal for the material of the partition wall member 82.

Moreover, recessed portions for the partition wall member 82 may be provided in the positioning members 84a and 84b, and the partition wall member 82 may be positioned by fitting both ends of the partition wall member 82 into the recessed portions.

Furthermore, the shape of the partition wall member 82 is not limited to a substantial plate shape. The shape of the partition wall member 82 may be any shape as long as the shape conforms to the shapes and the sizes of the coil components 100 and 200, the shape and the size of the third recessed portion 81, the amount of the filler 88 used, and others, and any shape may be employed depending on required specifications of the power conversion device 301. Specifically, for example, a protrusion may be provided at the center portion of the bottom surface of the partition wall member 82, and thus the partition wall member 82 and the deep bottom portion 83a as well as the partition wall member 82 and the shallow bottom portion 83b may be electrically connected.

Moreover, the number of coil components accommodated in the third recessed portion 81 is only required to be plural and is not limited to two.

In addition, the power conversion device 301 can adopt various modifications similar to those described in the first embodiment.

As described above, in the power conversion device 301 according to the second embodiment, the housing 31 is a die-cast molded product, and the third recessed portion 81 accommodates the plurality of coil components 100 and 200. As a result, the aspect ratio of the third recessed portion 81 can be lower, and thus the molding of the housing 31 by die-cast molding can be easier.

Furthermore, the plurality of coil components 100 and 200 are accommodated in the third recessed portion 81, and the partition wall member 82 is provided between the coil components 100 and 200. As a result, the heat radiation efficiency of the coil components 100 and 200 can be improved like in the power conversion device 300 of the first embodiment. In addition, it is possible to suppress propagation of the radiation noise emitted from the second coil component 200 to the first coil component 100, thereby obtaining the power conversion device 301 with reduced conduction noise.

### Third Embodiment

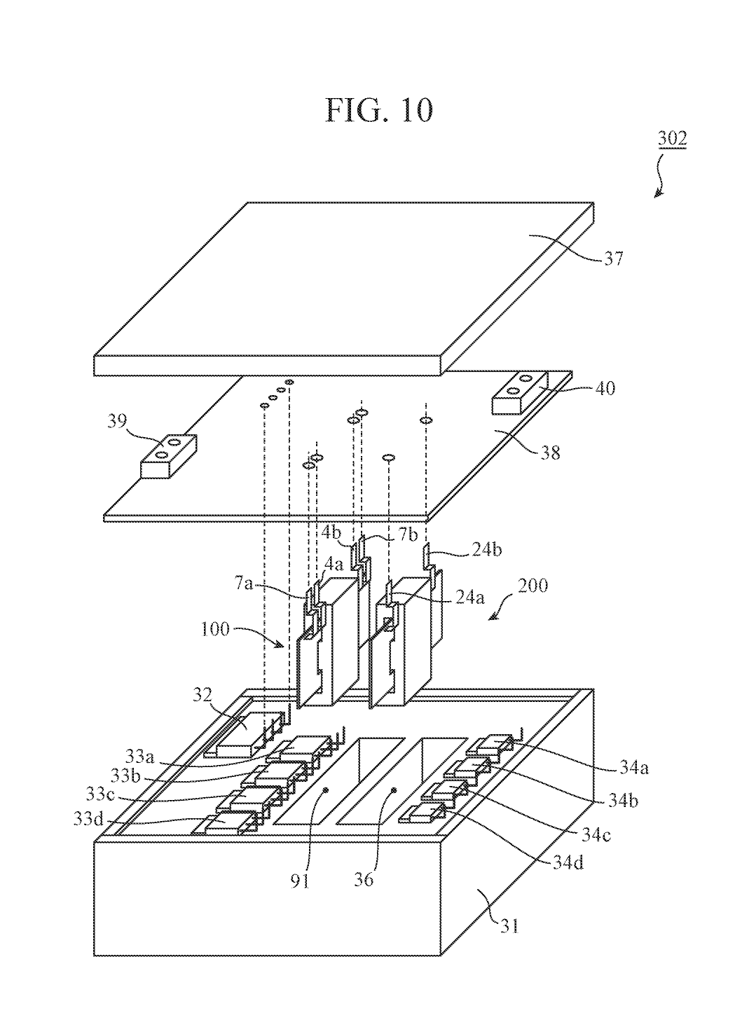

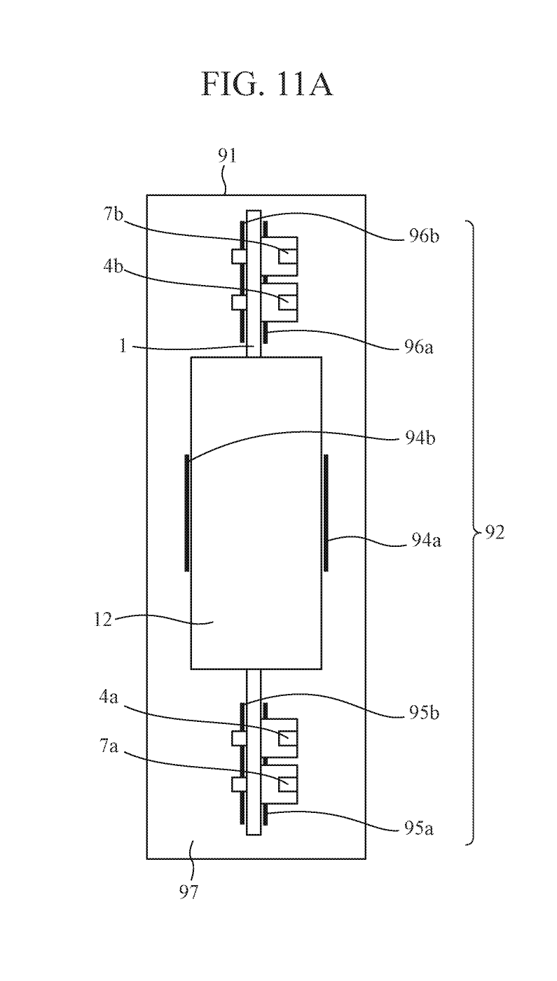

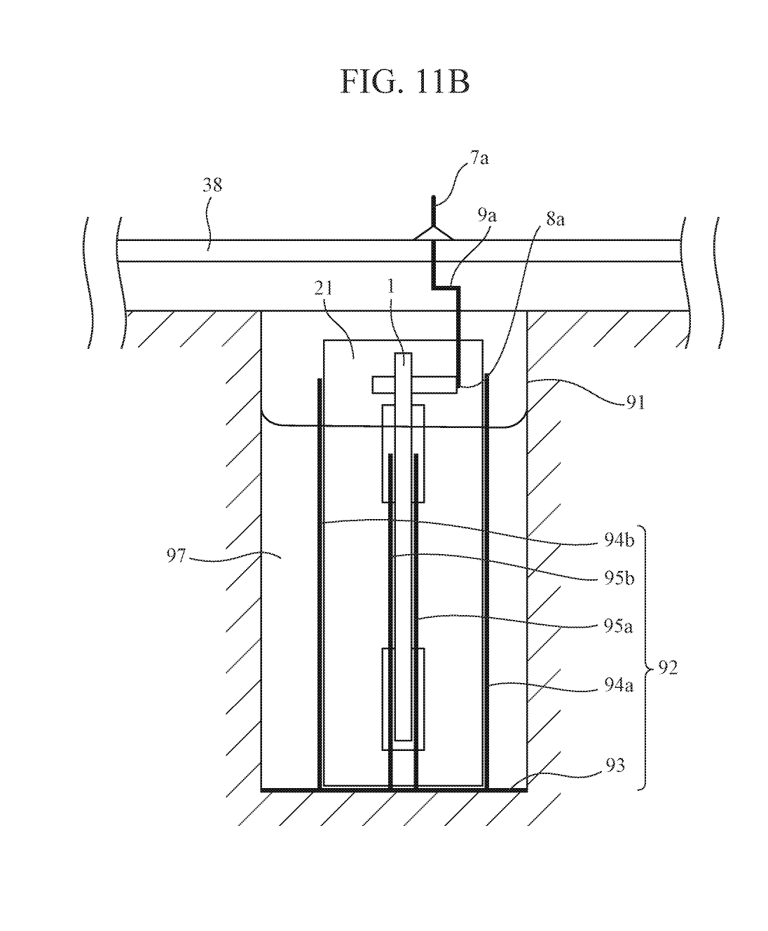

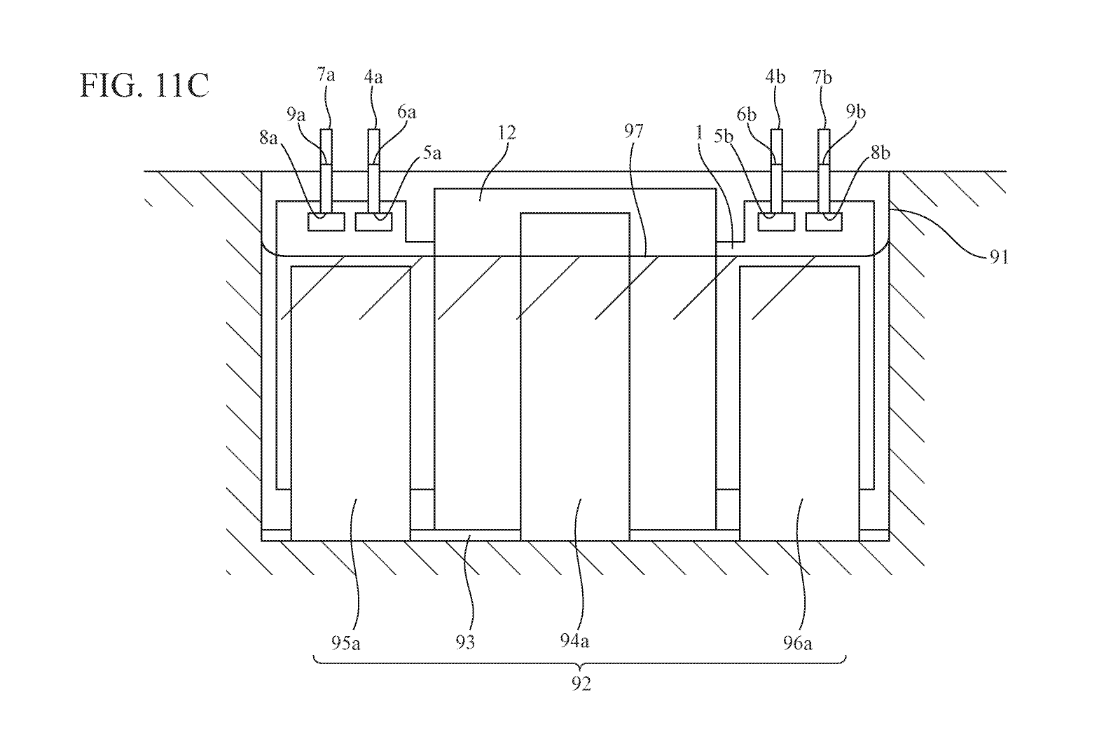

FIG. 10 is an exploded perspective view illustrating the main part of a power conversion device according to a third embodiment of the present invention. FIG. 11A is an explanatory diagram of a first coil component according to the third embodiment of the present invention accommodated in a first recessed portion when viewed from above. FIG. 11B is an explanatory diagram of the first coil component according to the third embodiment of the present invention accommodated in the first recessed portion when viewed from the front. FIG. 11C is an explanatory diagram of the first coil component according to the third embodiment of the present invention accommodated in the first recessed portion when viewed from a side. With reference to FIGS. 10 and 11, a power conversion device 302 of the third embodiment will be described. Note that components similar to those of the power conversion device 300 illustrated in FIGS. 1 to 5 are denoted by the same symbols, and description thereof is omitted.

A housing 31 has a bottomed first recessed portion 91 that opens toward the upper surface. The first recessed portion 91 has a shape similar to that of the second recessed portion 36, that is, a simple substantially rectangular parallelepiped. Inside the first recessed portion 91, a first coil component 100 is accommodated. The first coil component 100 is arranged vertically in the first recessed portion 91, and terminals 4a, 4b, 7a, and 7b protrude from an opening of the first recessed portion 91.

Here, inside the first recessed portion 91, a heat-radiating holding member 92 is accommodated together with the first coil component 100. The heat-radiating holding member 92 is made of a sheet metal such as aluminum. The heat-radiating holding member 92 includes a base surface 93 along the bottom surface of the first recessed portion 91, a pair of core holders 94a and 94b vertically extending from the base surface 93 and extending along both surfaces of the core 12, and two pairs of winding heat-radiating portions 95a and 95b and 96a and 96b extending from the base surface 93 and extending along both surfaces of the winding member 1. The inside of the first recessed portion 91 is filled with a filler 97 similar to the fillers 55, 64, and 88 of the first and the second embodiments.

The heat-radiating holding member 92 holds the first coil component 100 in the first recessed portion 91. That is, the heat-radiating holding member 92 has the function of positioning the first coil component 100 with respect to the first recessed portion 91 and also has the function of provisionally fixing the first coil component 100 before filling with the filler 97. Furthermore, the heat-radiating holding member 92 improves the heat radiation efficiency from the winding member 1 to the housing 31, in particular, by the winding heat-radiating portions 95a, 95b, 96a, and 96b. By implementing the functions by a single member, the number of parts can be reduced as compared to a structure in which each of the functions is implemented by a separate member. In addition, since the first recessed portion 91 has a simple shape similar to that of the second recessed portion 36, molding of the housing 31 is easy, and the manufacturing cost of the housing 31 can be reduced.

Note that the shape of the heat-radiating holding member 92 is not limited to the shape illustrated in FIG. 11. The heat-radiating holding member 92 may be of any shape as long as portions that perform functions equivalent to those of the base surface 93, the core holders 94a and 94b, and the winding heat-radiating portions 95a, 95b, 96a, and 96b are included.

In addition, in the second recessed portion 36, the positioning members 61a and 61b may be removed, and a heat-radiating holding member similar to the heat-radiating holding member 92 illustrated in FIG. 11 may be provided.

In addition, the power conversion device 302 of the third embodiment can adopt various modifications similar to those described in the first and the second embodiments.

As described above, in the power conversion device 302 of the third embodiment, the first coil component 100 is held by the heat-radiating holding member 92 provided in the first recessed portion 91. Since the heat-radiating holding member 92 serves as a heat radiation member, the number of parts of the power conversion device 302 can be reduced.

Note that the present invention may include a flexible combination of the embodiments, a modification of any component of the embodiments, or an omission of any component in the embodiments within the scope of the present invention.

### INDUSTRIAL APPLICABILITY

A power conversion device of the present invention can be used as an OBC for electric vehicles, a power conditioner for photovoltaic power generation systems, or the like for example.

### REFERENCE SIGNS LIST

1: Winding member, 2: Through hole, 3: Cutout portion, 4a, 4b: First terminal, 5a, 5b: First bent portion, 6a, 6b: Second bent portion, 7a, 7b: Second terminal, 8a, 8b: First bent portion, 9a, 9b: Second bent portion, 10: E-shaped core, 10a: Middle leg, 10b, 10c: Outer leg, 11: E-shaped core, 11a: Middle leg, 11b, 11c: Outer leg, 12: Core, 21: Winding member, 22: Through hole, 23: Cutout portion, 24a, 24b: Terminal, 25a, 25b: First bent portion, 26a, 26b: Second bent portion, 27: E-shaped core, 27a: Middle leg, 27b, 27c: Outer leg, 28: E-shaped core, 28a: Middle leg, 28b, 28c: Outer leg, 29: Core, 31: Housing, 32: First semiconductor element, 33a, 33b, 33c, 33d: Second semiconductor element, 34a, 34b, 34c, 34d: Third semiconductor element, 35: First recessed portion, 36: Second recessed portion, 37: Lid, 38: Main circuit printed board, 39: Input terminal, 40: Output terminal, 41: First capacitor, 42: Second capacitor, 43: Voltage current detecting circuit, 44: Photocoupler, 45: Control circuit, 51: Deep bottom portion, 52a, 52b: Positioning member, 53a, 53b: Groove, 54a, 54b, 54c: Gap, 55: Filler, 56a, 56b, 56c, 56d: Gap, 61a, 61b: Positioning member, 62a, 62b: Groove, 63a, 63b, 63c: Gap, 64: Filler, 65a, 65b, 65c, 65d: Gap, 71: First rectifier circuit, 72: First smoothing circuit, 73: Full bridge circuit, 74: Transformer circuit, 75: Second rectifier circuit, 76: Second smoothing circuit, 81: Third recessed portion, 82: Partition wall member, 83a: Deep bottom portion, 83b: Shallow bottom portion, 84a, 84b: Positioning member, 85a, 85b: First groove, 86a, 86b: Second groove, 87a, 87b, 87c, 87d, 87e, 87f, 87g: Gap, 88: Filler, 89a, 89b, 89c, 89d, 89e, 89f, 89g, 89h: Gap, 91: First recessed portion, 92: Heat-radiating holding member, 93: Base surface, 94a, 94b: Core holder, 95a, 95b: Winding heat-radiating portion, 96a, 96b: Winding heat-radiating portion, 97: Filler, 100: First coil component, 200: Second coil component, 300, 301, 302: Power conversion device, 400: Power conversion circuit.

1. A power conversion device, comprising:
a planer type coil component having a plate-like winding member and a core attached to the winding member;
a housing having a recessed portion in which the coil component is accommodated in vertical arrangement; and
a filler with which a gap between the recessed portion and the coil component is filled.

2. The power conversion device according to claim 1,
wherein the core is a burned product, and
a gap between the core and the winding member is filled with the filler.

3. The power conversion device according to claim 1,
wherein the winding member comprises a multilayer substrate and a coil pattern provided for an inner layer of the multilayer substrate.

4. The power conversion device according to claim 1,
wherein the housing is a die-cast molded product, and
a plurality coil components comprising the coil component is accommodated in the recessed portion.

5. The power conversion device according to claim 4,
wherein a transformer is configured by at least one of the plurality of coil components, and
a reactor is configured by at least another one of the coil components.

6. The power conversion device according to claim 1, further comprising:
a main circuit printed board arranged to face an opening of the recessed portion,
wherein a terminal of the coil component is electrically connected to the main circuit printed board.

7. The power conversion device according to claim 1,
wherein the coil component is positioned with respect to the recessed portion by a positioning member provided inside the recessed portion.

8. The power conversion device according to claim 1,
wherein a plurality of coil components comprising the coil component is accommodated in the recessed portion, and
a partition wall member is provided between the coil components.

9. The power conversion device according to claim 1,
wherein the coil component is held by a heat-radiating holding member provided inside the recessed portion.

10. The power conversion device according to claim 1,
wherein the power conversion device is mounted on a vehicle.

11. The power conversion device according to claim 1,
wherein the coil component has a terminal electrically connected to the winding member, and
the terminal has a spring characteristic.
